(19) United States
(12) Patent Application Publication
(10) Pub. No.: US 2024/0021768 A1
(43) Pub. Date: Jan. 18, 2024

(54) MICRO-NANO PIN LED ELECTRODE ASSEMBLY, MANUFACTURING METHOD THEREFOR, AND LIGHT SOURCE INCLUDING SAME

(71) Applicant: KOOKMIN UNIVERSITY INDUSTRY ACADEMY COOPERATION FOUNDATION, Seoul (KR)

(72) Inventor: Young Rag DO, Gahanna, OH (US)

(73) Assignee: KOOKMIN UNIVERSITY INDUSTRY ACADEMY COOPERATION FOUNDATION, Seoul (KR)

(21) Appl. No.: 18/058,154

(22) PCT Filed: Apr. 27, 2021
(86) PCT No.: PCT/KR2021/005311

§ 371 Date: Nov. 22, 2022

(30) Foreign Application Priority Data
May 25, 2020 (KR) 10-2020-0062462
May 25, 2020 (KR) 10-2020-0062463
Jun. 10, 2020 (KR) 10-2020-0070374

(51) Int. Cl. H01L 33/62; H01L 25/075; H01L 33/24; H01L 33/32; H01L 33/50; H01L 33/00

(52) U.S. Cl. CPC H01L 33/62; H01L 25/0753; H01L 33/24; H01L 33/32; H01L 33/502; H01L 33/0075; H01L 2933/0066

(57) ABSTRACT

The present invention relates to an LED electrode assembly, more particularly, to a micro-nanofin LED electrode assembly, a method for manufacturing the same, and a light source including the same.

### FIELD OF THE DISCLOSURE

The present invention relates to an LED electrode assembly, more particularly, to a micro-nanofin LED electrode assembly, a method for manufacturing the same, and a light source including the same.

### DESCRIPTION OF RELATED ART

Micro-light-emitting diodes (LEDs) and nano-LEDs may implement an excellent feeling of color and high efficiency and may be eco-friendly materials, thereby being used as core materials for displays. In line with such market conditions, recently, research for develofing new nanorod LED structures or shell-coated nano-cable LEDs through new manufacturing processes is being carried. In addition, research on a protective film material is being carried out to achieve high efficiency and high stability of a protective film covering an outer surface of nanorods, and research and development of a ligand material advantageous for a subsequent process is also being carried out.

Recently, display televisions using red, green, and blue micro-LEDs have been commercialized in line with research in such material fields. Displays or various light sources using micro-LEDs have advantages such as high performance characteristics, very long theoretical lifetime, and very high efficiency. However, since micro-LEDs should be individually placed on miniaturized electrodes in a limited area, an electrode assembly, which is implemented by placing micro-LEDs on the electrodes with pick place technology, is difficult to manufacture as true high-resolution commercial displays ranging from smartphones to TVs or light sources with various sizes, shapes, and brightness due to the limitations of process technology, considering a high unit price, a high process defect rate, and low productivity. In addition, it is more difficult to individually arrange nano-LEDs, which are smaller than micro-LEDs, on the electrodes with the same pick and place technology for micro-LEDs.

In order to overcome such difficulty, Korean Patent Registration No. 10-1490758 by the present inventor discloses an ultra-small LED electrode assembly manufactured through a method of self-aligning nanorod-type LED elements on an electrode by dropfing a solution mixed with nanorod-type LEDs on the electrode and then forming an electric field between two different electrodes. However, the nanorod type LEDs used have a problem in that a large number of LEDs must be mounted in order to express a desired efficiency because the efficiency is not good due to the small area from which light is emitted, and there is a problem with a high possibility of defects occurring in the nanorod-type LED itself.

Specifically, a method is known in which a nanopatterning process in combination with dry etching/wet etching are performed on an LED wafer to manufacture nanorod-type LED elements in a top-down manner, or nanorod-type LED elements are grown directly on a substrate in a bottom-up manner. In such nanorod-type LEDs, since a major axis of an LED coincides with a stack direction, that is, a stack direction of each layer in a p-GaN/InGaN multi-quantum well (MQW)/n-GaN stacked structure, an emission area is narrow. Since the emission area is narrow, surface defects have a relatively large effect on a decrease in efficiency, and it is difficult to optimize an electron-hole recombination rate, which may cause a problem in that luminous efficiency is significantly lower than that of an original wafer.

Therefore, there is an urgent need to develop an LED electrode assembly using a new LED material that can be easily arranged using an electric field, has a wide emission area, minimizes or prevents a decrease in efficiency due to surface defects, and has an optimized electron-hole recombination rate.

### SUMMARY

The present invention has been devised to solve the above problems, and an object of the present invention is to provide an electrode assembly using a micro-nanofin LED element having improved efficiency and luminance by increasing an emission area, a method for manufacturing the same, and a light source including the same.

In addition, another object of the present invention is to provide an electrode assembly using a micro-nanofin LED element capable of stably emitting light with high luminance by reducing the thickness of a photoactive layer while increasing an emission area, thereby preventing a decrease in efficiency due to surface defects, a method for manufacturing the same, and a light source including the same.

In addition, another object of the present invention is to provide an electrode assembly using a micro-nanofin LED element capable of preventing a decrease in electron-hole recombination efficiency due to an electron-hole velocity imbalance, a method for manufacturing the same, and a light source including the same.

Furthermore, another object of the present invention is to provide an electrode assembly using a micro-nanofin LED element capable of more easily self-aligning an LED element on an electrode by an electric field without a risk of an electrical short circuit, and having improved electrode arrangement design and ease of electrode implementation, and a method for manufacturing the same, and a light source including the same.

In order to achieve the above object, the present invention provides a method for manufacturing a micro-nanofin LED electrode assembly, comprising the steps of (1) adding a solution including a plurality of micro-nanofin LED elements on a lower electrode line including a plurality of lower electrodes spaced apart in a horizontal direction at a predetermined interval, wherein the micro-nanofin LED element is a rod-type element including a plane having a length and width of nano or micro size and a thickness perpendicular to the plane smaller than the length, and in which a first conductive semiconductor layer, a photoactive layer, a second conductive semiconductor layer, and an electrode layer or a polarization inducing layer are sequentially stacked in a thickness direction, (2) applying an assembly voltage to the lower electrode line so that the first conductive semiconductor layer, or electrode layer or polarization inducing layer of each of the plurality of micro-nanofin LED elements in the solution is in contact with at least two of the lower electrodes, thereby self-aligning the plurality of micro-nanofin LED elements, and (3) forming an upper electrode line on the plurality of self-aligned micro-nanofin LED elements.

According to an embodiment of the present invention, the predetermined interval may be smaller than the length of the micro-nanofin LED element.

In addition, the method may further include, between the steps (2) and (3), the steps of (4) forming an electrical contacting metal layer connecting between a side surface of the first conductive semiconductor layer, electrode layer, or polarization inducing layer of each of the micro-nanofin LED elements in contact with at least two of the lower electrodes and the contacted lower electrodes, and (5) forming an insulating layer on the lower electrode not to cover upper surfaces of the plurality of self-aligned micro-nanofin LED elements.

In addition, the length of the micro-nanofin LED element may be 1000 to 10000 nm, and the thickness of the micro-nanofin LED element may be 100 to 3000 nm.

In addition, the width of the micro-nanofin LED element may be greater or equal to the thickness of the micro-nanofin LED element.

In addition, a ratio of the length to the thickness of the micro-nanofin LED element may be 3:1 or more.

In addition, the micro-nanofin LED element may further include a protective film formed on a side surface of the micro-nanofin LED element to cover an exposed surface of the photoactive layer.

In addition, the polarization inducing layer may include a first polarization inducing layer and a second polarization inducing layer disposed adjacently along a longitudinal direction of the micro-nanofin LED element, and the first polarization inducing layer and the second polarization inducing layer may have different electrical polarities. In this case, as an example, the first polarization inducing layer may be ITO, and the second polarization inducing layer may be a metal or a semiconductor.

In addition, the present invention provides a micro-nanofin LED electrode assembly, including a lower electrode line including a plurality of lower electrodes spaced apart in a horizontal direction at a predetermined interval, a plurality of micro-nanofin LED elements which is a rod-type element including a plane having a length and width of nano or micro size and a thickness perpendicular to the plane smaller than the length, and in which a first conductive semiconductor layer, a photoactive layer, a second conductive semiconductor layer, and an electrode layer or a polarization inducing layer are sequentially stacked in a thickness direction, and in which the first conductive semiconductor layer, or the polarization inducing layer is disposed to be in contact with at least two adjacent lower electrodes, and an upper electrode line disposed on the plurality of micro-nanofin LED elements.

According to an embodiment of the present invention, one of the first conductive semiconductor layer and the second conductive semiconductor layer may include a p-type GaN semiconductor layer, and the other may include an n-type GaN semiconductor layer, a thickness of the p-type GaN semiconductor layer may be 10 to 350 nm, a thickness of the n-type GaN semiconductor layer is 100 to 3000 nm, and a thickness of the photoactive layer may be 30 to 200 nm.

In addition, a protrusion having a predetermined width and thickness may be formed on a lower surface of the first conductive semiconductor layer of the micro-nanofin LED element in a longitudinal direction of the micro-nanofin LED element.

In addition, the width of the protrusion may be formed to have a length of 50% or less compared to the width of the micro-nanofin LED element.

In addition, an emission area of the micro-nanofin LED element may be more than twice an area of a longitudinal cross-section of the micro-nanofin LED element.

In addition, 2 to 100,000 micro-nanofin LED elements may be included per unit area of 100×100 μm² of the micro-nanofin LED electrode assembly.

Hereinafter, the terms used in the present invention will be defined.

In descriptions of embodiments of the present invention, it should be understood that when a layer, region, pattern, or substrate is referred to as being “on,”, “upper”, “above,” “under,” “lower”, or “below” another layer, another region, or another pattern, the terminology of “on,” “upper”, “above,” “under,” “lower”, or “below” includes both the meanings of “directly” and “indirectly” “on,” “upper”, “above,” “under,” “lower”, or “below.”

The micro-nano fin LED electrode assembly according to the present invention is advantageous in achieving high luminance and light efficiency by increasing the emission area of the element, compared to the conventional electrode assembly using a rod-type LED element. In addition, since the area of the photoactive layer exposed to the surface is greatly reduced while increasing the emission area of the element, the efficiency decrease due to surface defects can be prevented or minimized, so that it is possible to implement an electrode assembly with excellent quality. Furthermore, the decrease in electron-hole recombination efficiency and the resulting decrease in luminous efficiency due to the electron-hole velocity imbalance of the used LED element is minimized in the electrode assembly, and thus, the electrode assembly can be effectively applied to the method of self-aligning the element on the electrode by an electric field. Thus, the electrode assembly can be more easily implemented, and thus it can be widely applied to various lighting, light sources, displays, and the like.

### BRIEF DESCRIPTION OF THE DRAWINGS

FIGS. 1 and 2 illustrate views of a micro-nanofin LED electrode assembly according to an embodiment of the present invention, wherein FIG. 1 is a plan view of a micro-nanofin LED electrode assembly, and FIG. 2 is a cross-sectional schematic view taken along the boundary line X-X′.

FIG. 3 is a cross-sectional schematic view of a micro-nanofin LED electrode assembly according to another embodiment of the present invention.

FIGS. 4A and 4B are schematic views of a first rod-type element in which a first conductive semiconductor layer, a photoactive layer, and a second conductive semiconductor layer are stacked in a thickness direction, respectively, and a second rod-type element in which a first conductive semiconductor layer, a photoactive layer, and a second conductive semiconductor layer are stacked in a longitudinal direction, respectively.

FIGS. 5 to 8 are views of a micro-nanofin LED element included in an embodiment of the present invention, wherein FIG. 5 is a perspective view of a micro-nanofin LED element, FIG. 6 is a cross-sectional view taken along the boundary line X-X′ of FIG. 5, FIG. 7 is a cross-sectional view taken along the boundary line Y-Y′ of FIG. 5, and FIG. 8 is a schematic view of a manufacturing process of a micro-nanofin LED element according to FIG. 5.

FIGS. 9 to 12 are views of a micro-nanofin LED element included in an embodiment of the present invention, wherein FIG. 9 is a perspective view of a micro-nanofin LED element, FIG. 10 is a cross-sectional view taken along the boundary line X-X′ of FIG. 9, FIG. 11 is a cross-sectional view taken along the boundary line Y-Y′ of FIG. 9, and FIG. 12 is a schematic view of a manufacturing process of a micro-nanofin LED element according to FIG. 9.

FIG. 13 is a schematic view of a light source according to an embodiment of the present invention.

FIGS. 14A and 14B are schematic views of a light source according to various embodiments of the present invention.

FIGS. 15 and 16 are schematic views of a medical device and beauty device according to an embodiment of the present invention, respectively.

### DETAILED DESCRIPTION OF THE INVENTION

Hereinafter, embodiments of the present invention will be described in detail with reference to the accompanying drawings such that those skilled in the art to which the present invention can easily carry out the present invention. It should be understood that the present invention may be embodied in various different forms and is not limited to the following embodiments.

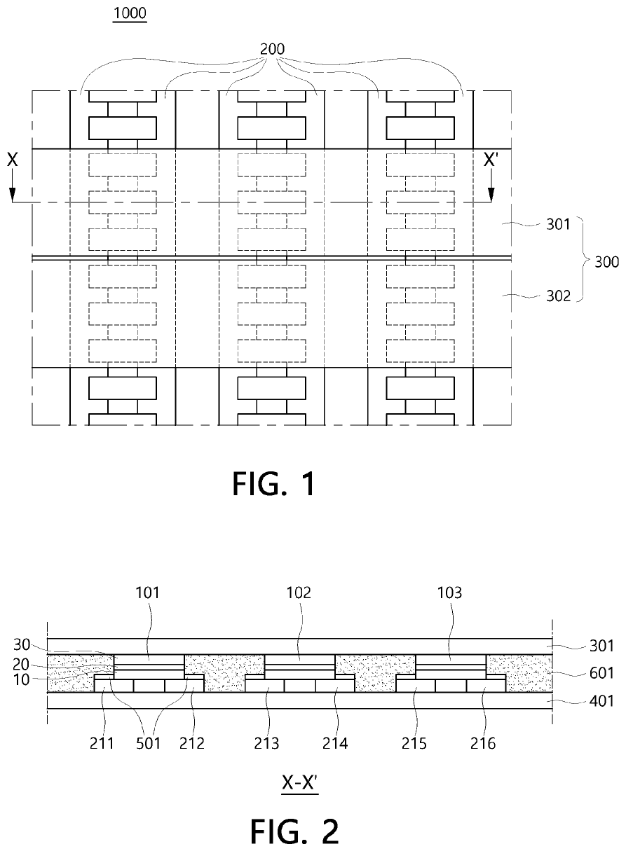

Referring to FIGS. 1 and 2, a micro-nanofin LED electrode assembly 1000 according to an embodiment of the present invention is implemented to include a lower electrode line 200 having a plurality of electrodes 211, 212, 213, 214 spaced apart in a horizontal direction at a predetermined interval, a plurality of micro-nanofin LED elements 101, 102, 103 disposed on the lower electrode line 200, and an upper electrode line 300 disposed in contact with upper portions of the micro-nanofin LED elements 101, 102, 103.

First, the electrode lines 200, 300 for self-aligning the micro-nanofin LED elements 101, 102, 103 and emitting light will be described.

The micro-nanofin LED electrode assembly 1000 includes the upper electrode line 300 and the lower electrode line 200 disposed to face the upper and lower portions with the micro-nano-fin LED elements 101, 102, 103 interposed therebetween. Since the upper electrode line 300 and the lower electrode line 200 are not disposed in a horizontal direction, the electrode design can be very simple and can be implemented more easily by deviating from the complicated electrode line of the conventional electrode assembly by an electric field induction in which two types of electrodes realized to have ultra-small thickness and width are disposed to have micro or nano unit spacing in the horizontal direction within a plane of a limited area.

Specifically, the conventional electrode assembly implemented by self-aligning elements through the electric field induction also uses horizontally spaced electrodes as assembly electrodes to mount rod-type micro LED elements on the assembly electrode, and uses the same electrode, that is, the assembled electrode as it is, as the driving electrode. On the contrary, the lower electrode line 200 provided in an embodiment of the present invention functions as an assembled electrode, but since only one surface of the first conductive semiconductor layer or one surface of the second conductive semiconductor is in contact on the lower electrode line 200, the micro-nanofin LED element 101, 102, 103 cannot be emitted using only the lower electrode line 200, which is distinguished from the conventional electrode assembly through the electric field induction. This distinction causes a significant difference in the degree of freedom of electrode design and the ease of electrode design.

In other words, in the case that the same electrode is used for the assembled electrode and the driving electrode, it needs to realize a structure capable of mounting a rod-type ultra-small LED element in as many numbers as possible in the plane of a limited area, and at the same time, and electrode lines to which different voltages are applied at micro-nano-sized intervals. Therefore, it was not easy in the design or implementation of the electrode structure. However, since the same type of power (e.g., (+) or (−) power) is applied to the lower electrode line 200 included in the present invention when driving, there is little risk of an electrical short between the lower electrodes 211,212,213,214,215,216 in the lower electrode line 200. In addition, conventionally, both ends of each rod-type micro LED element corresponding to a different conductive semiconductor layer had to be in contact with adjacent electrodes in a one-to-one correspondence such that light could be emitted without an electrical short circuit. Accordingly, if each rod-type micro LED element was disposed across three or four adjacent electrodes, the photoactive layer of the rod-type micro LED element inevitably contacted the electrode, resulting in a short circuit. Considering that, there was a difficulty in designing the width and spacing between electrodes. However, in the micro-nanofin LED element 101, 102, 103 included in the present invention, since one surface of the first conductive semiconductor layer or one surface of the second conductive semiconductor layer is in contact with the lower electrode line, even if the first or second conductive semiconductor layer is spread over several adjacent lower electrodes 211, 212, 213, 214, 215, 216, an electrical short does not occur, which has an advantage in that the lower electrode line 200 can be more easily designed.

In addition, the upper electrode line 300 is provided so that electrical contact is possible on the upper surface of the micro-nanofin LED elements 101, 102, 103 disposed as illustrated in FIGS. 1 and 2, so there is an advantage of being very easy to design or implement an electrode. In particular, although FIG. 1 illustrates that the upper electrode line 300 is divided into a first upper electrode 301 and a second upper electrode 302, the upper electrode can be implemented with only one electrode in contact with the upper surfaces of all the disposed micro-nanofin LED elements. Thus, there is an advantage of greatly simplifying the electrode line, compared to the conventional art.

The lower electrode line 200 is an assembly electrode for self-aligning the micro-nanofin LED element 101, 102, 103 so that the upper or lower surface in the thickness direction of the micro-nano-fin LED element 101, 102, 103 is in contact with the electrode line. At the same time, the lower electrode line 200 may function as one of the driving electrodes provided to light the micro-nanofin LED element 101, 102. 103 along with the electrode line 300 to be described later.

In addition, the lower electrode line 200 is implemented to include a plurality of lower electrodes 211, 212, 213, 214, 215, 216 spaced apart in the horizontal direction at a predetermined interval. The electrodes 211,212,213,214,215,216 may be included in appropriately set number and spacings between the electrodes in consideration of the function as an assembled electrode, the length of the element, the size of the electrode assembly, and the like.

In addition, the plurality of lower electrodes 211, 212, 213, 214, 215, 216 included in the lower electrode line 200 is not limited in specific electrode arrangement as long as they are arranged spaced apart in the horizontal direction. For example, the lower electrode line 200 may have a structure in which the plurality of electrodes is spaced apart by a predetermined interval in one direction and arranged side by side.

In addition, the distance between the adjacent lower electrodes 211, 212, 213, 214, 215, 216 may be smaller than the length of the micro-nanofin LED element 101, 102, 103. If the distance between the two adjacent electrodes is equal or wider than the length of the micro-nanofin LED element, the micro-nanofin LED element can be self-aligned in a form sandwiched between two adjacent electrodes. In this case, it is not preferable because there is a high possibility that an electrical short circuit may occur due to contact between the side surface of the electrode and the photoactive layer exposed on the side surface of the micro-nanofin LED element.

On the other hand, the lower electrode line 200 may be provided directly on a support body 1100, 1100′, 1100″, which will be described later, but otherwise the lower electrode line 200 may be provided on a separate base substrate 401, and the base substrate 401 may be disposed to be placed on the support body 1100, 1100′, 1100″. The base substrate 401 may function as a support body for supporting the lower electrode line 200, the upper electrode line 300, and the micro-nanofin LED element 101, 102, 103 interposed between the lower electrode line 200 and the upper electrode line 300. The base substrate 401 may be any one selected from the group consisting of glass, plastic, ceramic, and metal, but is not limited thereto. In addition, a transparent material may be preferably used for the base substrate 401 in order to minimize loss of emitted light. In addition, the base substrate 401 may preferably be a flexible material. In addition, the size and thickness of the base substrate 401 may be appropriately changed in consideration of the size of the provided micro-nanofin LED electrode assembly, the specific design of the lower electrode line 200, and the like.

Next, in the case that the upper electrode line 300 is designed to be in electrical contact with the upper portions of the micro-nanofin LED elements 101, 102, 103 mounted on the lower electrode line 200, the number, arrangement, shape, etc. of the upper electrode line 300 are not limited. However, as illustrated in FIG. 1, if the lower electrode lines 200 are arranged side by side in one direction, the upper electrode line 300 may be arranged to be perpendicular to the one direction, and such electrode arrangement is an electrode arrangement that has been widely used in conventional displays and the like, and has the advantage of being able to use the electrode arrangement and driving control technology of the conventional display field as it is.

Meanwhile, FIG. 1 illustrates only the first upper electrode 301 and the second upper electrode 302 so that the upper electrode line 300 including them covers only some elements, but this figure has omitted parts for ease of description. As such, it should be noted that there are unillustrated upper electrodes disposed on the upper portions of the micro-nanofin LED elements.

The lower electrode line 200 and the upper electrode line 300 may have the material, shape, width, and thickness of an electrode used in a typical LED electrode assembly, and can be manufactured using a known method, so the material, shape, width, and thickness are not specifically limited in the present invention. For example, the electrode may be aluminum, chromium, gold, silver, copper, graphene, ITO, or an alloy thereof, and may have a width of 2 to 50 μm and a thickness of 0.1 to 100 μm, but may be appropriately changed in consideration of the size and the like of a desired LED electrode assembly.

Next, the micro-nanofin LED element 101, 102, 103 disposed between the above-described lower electrode line 200 and the upper electrode line 300 will be described.

The micro-nanofin LED element 101, 102, 103 according to an embodiment of the present invention includes a first conductive semiconductor layer 10, a photoactive layer 20, and a second conductive semiconductor layer 30, and is a rod-type LED element of which thickness direction is a stacking direction of these layers and which has a length longer than thickness.

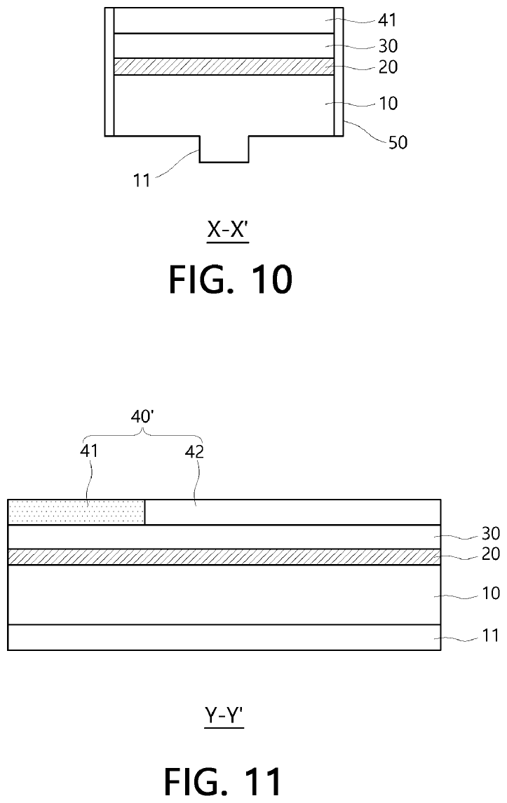

Referring to FIGS. 5 to 7 and 9 to 11, based on the mutually perpendicular X, Y, and Z axes, the X-axis direction is the length, the Y-axis direction is the width, and the Z-axis direction is the thickness. In this case, the micro-nanofin LED element 108, 109 according to an embodiment of the present invention is a rod-type element in which the length is a major axis, the thickness is a minor axis, and the length is greater than the thickness, and in which the first conductive semiconductor layer 10, the photoactive layer 20, the second conductive semiconductor layer 30, and an electrode layer 40 or a polarization inducing layer 40′ are sequentially stacked in the thickness direction.

More specifically, the micro-nanofin LED element 108, 109 has a predetermined shape in an X-Y plane consisting of a length and a width, in which a direction perpendicular to the plane becomes a thickness direction, and the respective layers constituting the LED element are stacked in the thickness direction. The micro-nanofin LED element 108, 109 of this structure has the advantage of securing a wider emission area through a plane consisting of a length and a width even if the thickness of the photoactive layer 20 in the portion exposed to the side surface is thin. In addition, due to this, the emission area of the micro-nanofin LED element 108, 109 according to an embodiment of the present invention may have a wide emission area exceeding twice the area of the longitudinal cross-section of the micro-nanofin LED element. Here, the longitudinal cross-section is a cross-section parallel to the X-axis direction, which is the longitudinal direction, and may be the X-Y plane in the case of the element having a constant width.

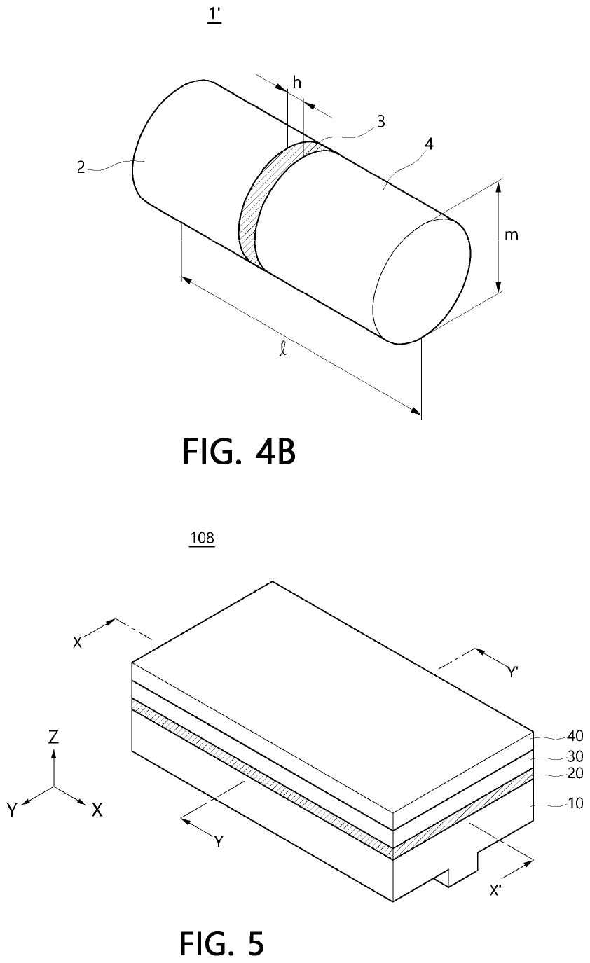

Specifically, referring to FIGS. 4A and 4B, both a first rod-type element 1 illustrated in FIG. 4A and a second rod-type element 1′ illustrated in FIG. 4B are rod-type elements having a structure in which a first conductive semiconductor layer 2, a photoactive layer 3, and a second conductive semiconductor layer 4 are stacked, and in which the length (f) and the thickness (m) are the same, and the thickness (h) of the photoactive layer is also the same.

However, in the first rod-type element 1, the first conductive semiconductor layer 2, the photoactive layer 3, and the second conductive semiconductor layer 4 are stacked in the thickness direction, whereas in the second rod-type element 1′, the first conductive semiconductor layer 2, the photoactive layer 3, and the second conductive semiconductor layer 4 are stacked in the longitudinal direction.

These two elements 1, 1′ have a large difference in the emission area. For example, assuming that the length ( [symbol] ) is 4000 nm, the thickness (m) is 600 nm, and the thickness (h) of the photoactive layer 3 is 100 nm, the ratio of the surface area, which corresponds to the emission area, of the photoactive layer 3 of the first rod-type element 1 and the surface area of the photoactive layer 3 of the second rod-type element 1′ is 6.42 μm²:0.6597 μm², the emission area of the first rod-type element 1, which is the micro-nanofin LED element, is 9.84 times larger than the emission area of the second rod-type element 2. In addition, the ratio of the surface area of the photoactive layer 3 exposed to the outside in the emission area of the total photoactive layer in the first rod-type element 1 is similar to that in the second rod-shaped element 1′. However, since the absolute value of the increased unexposed surface area of the photoactive layer 3 is much greater in the first rod-type element 1, the effect of the exposed surface area on excitons is much less. Accordingly, the effect of surface defects on excitons in the first rod-type element 1, which is the micro-nanofin LED element, is much smaller than that in the second rod-type element 1′, which is the horizontally arranged rod-type element. Accordingly, in terms of luminous efficiency and luminance, it can be evaluated that the first rod-type element 1, which is the micro-nanofin LED element, is significantly superior to the second rod-type element 1′, which is the horizontally arranged rod-type element. In addition, in the case of the second rod-type element 1′, a wafer on which a conductive semiconductor layer and a photoactive layer are stacked in the thickness direction is etched in the thickness direction. As a result, the long length of the element corresponds to the wafer thickness, and in order to increase the length of the element, an increase in the etched depth is unavoidable. The greater the etched depth, the higher the possibility of occurrence of defects on the element surface. As a result, even if the area of the exposed photoactive layer in the second rod-type element 1′ is smaller than that in the first rod-shaped element 1, the possibility of surface defects increases, and when considering the reduction in luminous efficiency due to the increase in the possibility of surface defects, it can be expected that the first rod-type element 1 is ultimately excellent in luminous efficiency and luminance.

Furthermore, with respect to the movement distance of the holes injected from any one of the first conductive semiconductor layer 2 and the second conductive semiconductor layer 4 and the electrons injected from the other, the first rod-type element 1 is shorter than the second rod-type element 1′, and thus the probability of being captured by defects on the wall during electron and/or hole movement is reduced, so it is possible to minimize emission loss, and it is advantageous to minimize emission loss due to electron-hole velocity imbalance. In addition, in the case of the second rod-type element 1′, a strong optical path behavior occurs due to the circular rod-type structure, so the light path generated by electron-holes resonates in the longitudinal direction, so that light is emitted from both ends in the longitudinal direction. Thus, in the case that the element is placed lying down, the front emission efficiency is not good due to the strong side emission profile. On the other hand, in the case of the first rod-type element 1, since light is emitted from the upper surface and the lower surface, there is an advantage of expressing excellent front luminous efficiency.

In the micro-nanofin LED element 108, 109 included in an embodiment of the present invention, the conductive semiconductor layers 10, 30 and the photoactive layer 20 are stacked in the thickness direction, like the first rod-type element 1 described above, so that the micro-nanofin LED element 108, 109 can have a more improved emission area by implementing the length longer than the thickness. Furthermore, even if the area of the exposed photoactive layer 20 is slightly increased, since the element is the rod-type in which the thickness is smaller than the length, the etched depth is shallow, so the possibility of defects occurring on the exposed surface of the photoactive layer 20 can be reduced. Accordingly, it is advantageous to minimize or prevent a decrease in luminous efficiency due to defects.

Although the plane is illustrated as a rectangle in FIG. 5, it is not limited thereto, and it can be employed without limitation, from a general rectangular shape such as a rhombus, a parallelogram, and a trapezoid to an oval.

The micro-nanofin LED element 108, 109 according to an embodiment of the present invention has a size of micro or nano units in length and width, for example, the length of the micro-nanofin LED element 108, 109 may be 1000 to 10000 nm. and the width of the micro-nanofin LED element 108, 109 may be 250 to 1500 nm. In addition, the thickness may be 100 to 3000 nm. The standard of the length and width may be different depending on the shape of the plane. For example, in a case in which the plane is a rhombus or a parallelogram, one of the two diagonals may be the length and the other may be the width, and in the case in which the plane is a trapezoid, a long side of the height, the upper side, and the bottom side may be a length, and a short side perpendicular to the long side may be a width. Alternatively, in the case in which the plane is an ellipse, the major axis of the ellipse may be the length and the minor axis of the ellipse may be the width.

In this case, the ratio of the length to the thickness of the micro-nanofin LED element 108, 109 may be 3:1 or more, more preferably 6:1 or more, and thus the length may be greater than the thickness. Through this, there is an advantage of more easily self-aligning the micro-nanofin LED element on the lower electrode line 200 through electric field to be described later. If the length and thickness ratio of the micro-nanofin LED element 108, 109 is reduced to less than 3:1, it may be difficult to self-align the micro-nanofin LED element on the lower electrode through an electric field, and the element may not be fixed on the electrode. Thus, there is a risk that an electrical contact short-circuit caused by a process defect may be caused. However, the ratio of the length to the thickness may be 15:1 or less, and through this, it may be advantageous to achieve the object of the present invention, such as optimization of a rotation torque that can make self-alignment using an electric field.

In addition, in the micro-nanofin LED element 108, 109, the width may be greater than or equal to the thickness. Accordingly, when the micro-nanofin LED element 108, 109 is aligned on at least two adjacent lower electrodes using the electric field, there is an advantage of minimizing or preventing alignment by lying on the side. In the case in which the micro-nanofin LED element is disposed lying on its side, even if alignment and mounting are achieved in which one end and the other end in the longitudinal direction of the LED element respectively contact at least two spaced lower electrodes, an electrical short may occur as the photoactive layer exposed on the side surface of the element contacts the lower electrode, as a result, there is a risk that light cannot be emitted.

In addition, the micro-nanofin LED element 108, 109 may be an element having different sizes at both ends in the longitudinal direction. For example, the micro-nanofin LED element 108, 109 may be a rod-type element having a rectangular plane that is an equilateral trapezoid whose length, which is the height, is greater than the upper and lower sides. According to the difference in length between the upper and lower sides, a difference between positive and negative charges accumulated at both ends of the element in the longitudinal direction may occur accordingly. Through this, there is an advantage that self-alignment can be easily implemented by the electric field.

In addition, on the lower surface of the first conductive semiconductor layer 10 of the micro-nanofin LED element 108, 109, a protrusion 11 having a predetermined width and thickness may be formed in the longitudinal direction of the element. The protrusion 11 will be described in detail in the description of the manufacturing method to be described later, but the protrusion 11 may be formed by etching the wafer in the thickness direction, and then horizontal etching inward from both sides of the lower portion of the etched LED part in the central part in order to remove the etched LED part from the wafer. The protrusion 11 may help to perform an improved function for the extraction of the front emission of the micro-nanofin LED element 108, 109. In addition, when the micro-nanofin LED element 108, 109 is self-aligned on the lower electrode line 200, the protrusion 11 may help to control the alignment so that the opposite surface of one surface of the element on which the protrusion 11 is formed is positioned on the lower electrode line 200. Furthermore, after the opposite surface is positioned on the lower electrode line 200, the upper electrode line 300 may be formed on one surface of the element on which the protrusion 11 is formed for light emission of the element. As the protrusion 11 increases the contact area with the upper electrode line 300 to be formed, it may be advantageous to improve the mechanical coupling force between the upper electrode line 300 and the micro-nanofin LED element 108, 109.

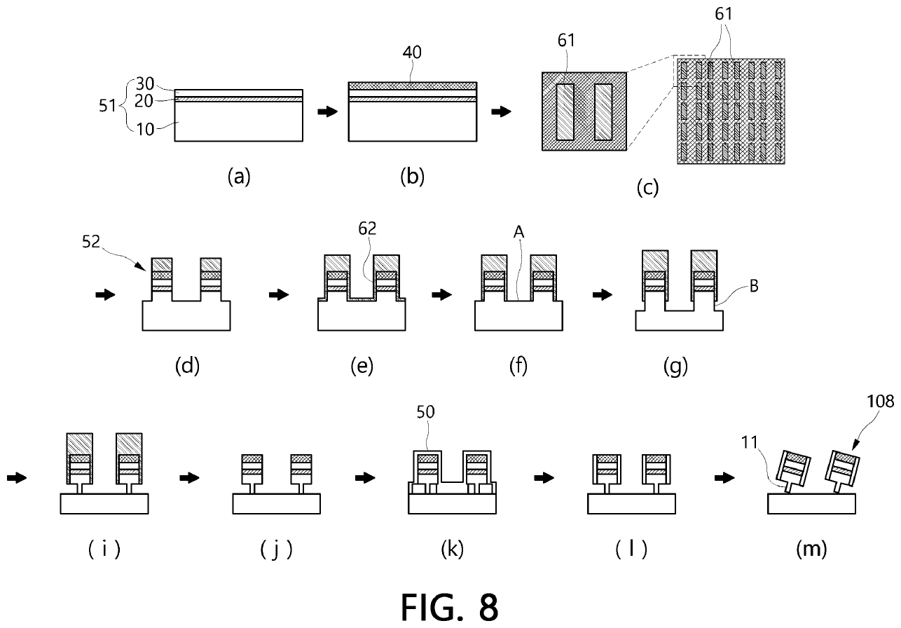

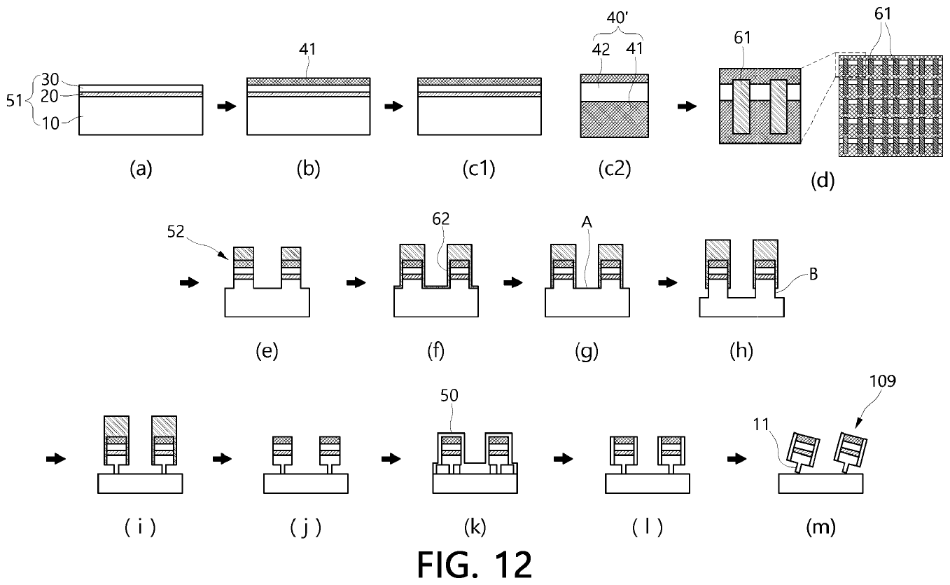

In this case, the width of the protrusion 11 may be formed to be 50% or less, more preferably, 30% or less of the width of the micro-nanofin LED element 108, 109, and through this, the separation of the etched part of the micro-nanofin LED element from the LED wafer may be easier. If the protrusion is formed to exceed 50% of the width of the micro-nanofin LED element 108, 109, it may not be easy to separate the etched part of the micro-nanofin LED element from the LED wafer. In addition, there is a possibility that the mass productivity and/or quality may be deteriorated due to cutting or separation occurring in parts other than the intended part, and the length and quality uniformity of the micro-nanofin LED elements produced in plurality may be reduced. Meanwhile, the width of the protrusion 11 may be formed to be 10% or more of the width of the micro-nanofin LED element 108, 109. If the width of the protrusion is formed to be less than 10% of the width of the micro-nanofin LED element 108, 109, the separation from the LED wafer may be easy, but during side etching (see (g) in FIG. 8/(i) in FIG. 8 and (h) in FIG. 12/(i) in FIG. 12) to be described later, due to excessive etching, there is a risk that even a portion of the first conductive semiconductor layer 10 that should not be etched may be etched, and the effect according to the above-described protrusion 11 may not be expressed. In addition, there is a risk of separation by a wet etching solution, and there may be a problem in that the micro-nanofin LED element dispersed in a high-risk etching solution having a strong basic property needs to be cleaned by separating the micro-nanofin LED element from the wet etching solution. On the other hand, the thickness of the protrusion 11 may have a thickness of 10 to 30% of the thickness of the first conductive semiconductor layer, through which the first conductive semiconductor layer can be formed to a desired thickness and quality, and it may be more advantageous to express the effect through the protrusion 11. Here, the thickness of the first conductive semiconductor layer 10 refers to a thickness based on the lower surface of the first conductive semiconductor layer on which the protrusion is not formed.

As a specific example, the width of the protrusion 11 may be 50 to 300 nm, and the thickness of the protrusion 11 may be 50 to 400 nm.

Hereinafter, each layer included in the micro-nanofin LED element 108, 109 will be described in detail.

The micro-nanofin LED element 108, 109 includes a first conductive semiconductor layer 10 and a second conductive semiconductor layer 30. A conductive semiconductor layer employed in a typical LED element used for a lighting, a display, and the like may be used as the conductive semiconductor layer without limitation. According to a preferred embodiment of the present invention, any one of the first conductive semiconductor layer 10 and the second conductive semiconductor layer 30 may include at least one n-type semiconductor layer, and the other conductive semiconductor layer may include at least one p-type semiconductor.

In the case that the first conductive semiconductor layer 10 includes an n-type semiconductor layer, the n-type semiconductor layer may include a semiconductor material having an empirical formula of InₓAl_{y}Ga_{1-x-y}N (0≤x≤1, 0≤y≤1, and 0≤x+y≤1), for example, at least one selected from among InAlGaN, GaN, AlGaN, InGaN, AN, InN, and the like and may be doped with a first conductive dopant (for example, Si, germanium (Ge), or tin (Sn)).

According to one preferred embodiment of the present invention, the first conductive semiconductor layer 10 may have a thickness of 1 to 3 μm, but the present invention is not limited thereto.

In the case that the second conductive semiconductor layer 30 includes a p-type semiconductor layer, the p-type semiconductor layer may include a semiconductor material having an empirical formula of InₓAl_{y}Ga_{1-x-y}N (0≤x≤1, 0≤y≤1, and 0≤x+y≤1), for example, at least one selected from among InAlGaN, GaN, AlGaN, InGaN, AlN, and InN, and the like, and may be doped with a second conductive dopant (for example, magnesium (Mg)). According to one preferred embodiment of the present invention, the second conductive semiconductor layer 30 may have a thickness of 0.01 to 0.30 μm, but the present invention is not limited thereto

According to an embodiment of the present invention, one of the first conductive semiconductor layer 10 and the second conductive semiconductor layer 30 includes a p-type GaN semiconductor layer, and the other includes an n-type GaN semiconductor layer. The p-type GaN semiconductor layer may have a thickness of 10 to 350 nm, and the n-type GaN semiconductor layer may have a thickness of 1000 to 3000 nm. Through this, the movement distance of the holes injected into the p-type GaN semiconductor layer and electrons injected into the n-type GaN semiconductor layer is shorter compared to the rod-type element in which the semiconductor layers and the photoactive layer are stacked in the longitudinal direction as illustrated in FIG. 4B, and this reduces the probability of electrons and/or holes being captured by defects on the wall during movement, thereby minimizing the emission loss, and it can be advantageous to minimize the emission loss due to electron-hole velocity imbalance as well.

Then, the photoactive layer 20 is formed on the first conductive semiconductor layer 10, and may be formed to have a single or multi-quantum well structure. A photoactive layer included in a typical LED element used for a light, a display, and the like may be used as the photoactive layer 20 without limitation. A clad layer (not illustrated) doped with a conductive dopant may be formed on and/or below the photoactive layer 20, and the clad layer doped with the conductive dopant may be implemented as an AlGaN layer or an InAlGaN layer. In addition, a material such as AlGaN or AlInGaN may be used for the photoactive layer 20. In the photoactive layer 20, when an electric field is applied to an element, electrons and holes moving from the conductive semiconductor layers positioned on and below the photoactive layer to the photoactive layer are combined to generate electron-hole pairs in the photoactive layer, thereby emitting light. According to one preferred embodiment of the present invention, the photoactive layer 20 may have a thickness of 30 nm to 300 nm, but the present invention is not limited thereto.

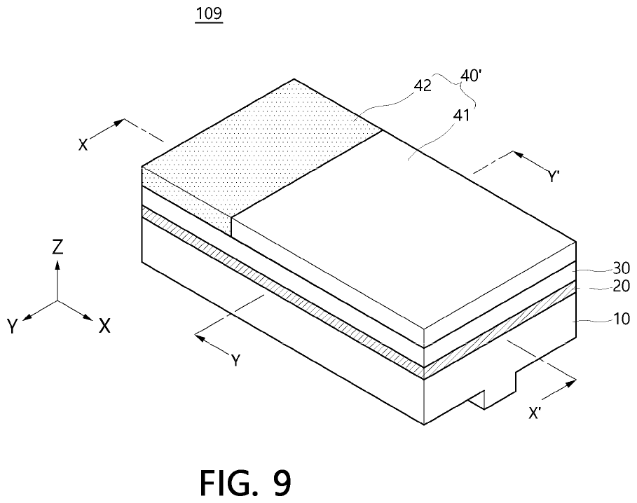

Then, an electrode layer 40 may be formed on the second conductive semiconductor layer 30 as illustrated in FIGS. 5 to 7 or a polarization inducing layer 40′ may be formed as illustrated in FIGS. 9 to 11.

First, the case in which the electrode layer 40 is formed will be described. An electrode layer included in a typical LED element used for a light, a display, and the like may be used as the electrode layer 40 without limitation. The electrode layer 40 may be made of a material of chromium (Cr), titanium (Ti), aluminum (Al), gold (Au), nickel (Ni), indium tin oxide (ITO), and oxides or alloys thereof alone, or a mixture thereof, but preferably a transparent material to minimize the emission loss. An example may be ITO. In addition, the electrode layer 40 may have a thickness of 50 to 500 nm, but the present invention is not limited thereto.

In addition, the case in which the polarization inducing layer 40′ is formed will be described. The polarization inducing layer 40′ is a layer that may more easily achieve self-alignment due to an electric field by allowing both ends of the micro-nanofin LED element 109 in the longitudinal direction to have different electrical polarities from each other. At the same time, the polarization inducing layer 40′ may function as an electrode layer by increasing conductivity when a material such as metal is used for the polarization inducing layer 40′. The polarization inducing layer 40′ may include a first polarization inducing layer 41 disposed on one end side in the longitudinal direction of the element, and a second polarization inducing layer 42 disposed on the other end side in the longitudinal direction of the element. In this case, the first polarization inducing layer 41 and the second polarization inducing layer 42 may have different electrical polarities. For example, the first polarization inducing layer 41 may be ITO, and the second polarization inducing layer 42 may be a metal or a semiconductor. In addition, the thickness of the polarization inducing layer 40′ may be 50 to 500 nm, but is not limited thereto. The first polarization inducing layer 41 and the second polarization inducing layer 42 may be disposed in the same area by dividing the upper surface of the second conductive semiconductor layer 30 in two, but is not limited thereto. Either one of the first polarization inducing layer 41 and the second polarization inducing layer 42 may be disposed to have a larger area.

The first conductive semiconductor layer 10, the photoactive layer 20, the second conductive semiconductor layer 30, and the electrode layer 40 or the polarization inducing layer 40′ may be included as minimum components of the micro-nanofin LED element 108, 109, and another phosphor layer, active layer, semiconductor layer, hole block layer, and/or electrode layer may be further included on/below each layer.

Meanwhile, the micro-nanofin LED element 108, 109 may further include a protective film 50 formed on the side surface to cover the exposed surface of the photoactive layer 20. The protective film 50 is a film for protecting the exposed surface of the photoactive layer 20, and covers at least all the exposed surface of the photoactive layer 20, for example, both sides and both front and rear end surfaces of the micro-nanofin LED element 108, 109. The protective film 50 may include, for example, at least one of silicon nitride (Si₃N₄), silicon dioxide (SiO₂), aluminum oxide (Al₂O₃), hafnium oxide (HfO₂), zirconium oxide (ZrO₂), yttrium oxide (Y₂O₃), titanium dioxide (TiO₂), aluminum nitride (AlN), and gallium nitride (GaN), more preferably the protective film 50 may be made of the above component, but may be transparent, but is not limited thereto. According to one preferred embodiment of the present invention, the protective film may have a thickness of 5 to 100 nm, but is not limited thereto.

The above-described micro-nanofin LED element 108, 109 may be manufactured by a manufacturing method described below, but is not limited thereto.

Referring to FIGS. 8 and 12, the micro-nanofin LED element 108, 109 may be manufactured by including the steps of (A) preparing an LED wafer 51 in which the first conductive semiconductor layer 10, the photoactive layer 20, and the second conductive semiconductor layer 30 are sequentially stacked, (B) forming the electrode layer 40 or the polarization inducing layer 40′ patterned so that different electrical polarities are adjacent to each other on the second conductive semiconductor layer 30 of the LED wafer 51, (C) forming a plurality of micro-nanofin LED structures 52 by etching the LED wafer 51 in the thickness direction so that each element has a plane having a length and width of nano or micro size, and in which a thickness perpendicular to the plane is smaller than the length, and (D) separating the plurality of micro-nanofin LED structures 52 from the LED wafer 51.

Referring to FIG. 8, the micro-nanofin LED element 100 in which the electrode layer 40 is formed on the second conductive semiconductor layer 30 will be described. As step (A) of the present invention, the step of preparing the LED wafer 51 in which the first conductive semiconductor layer 10, the photoactive layer 20, and the second conductive semiconductor layer 30 are sequentially stacked on a substrate (not illustrated) is performed.

Since the description of each layer provided in the LED wafer 51 is the same as that described above, a detailed description thereof will be omitted, and the description will be made focusing on parts not described. First, the thickness of the first conductive semiconductor layer 10 in the LED wafer 51 may be thicker than the thickness of the first conductive semiconductor layer 10 in the above-mentioned micro-nanofin LED element 100. In addition, each layer in the LED wafer 51 may have a c-plane crystal structure.

In addition, the LED wafer 51 may be subjected to a cleaning process, and since a cleaning process and a cleaning solution of a typical wafer may be appropriately applied in the cleaning process, the present invention is not particularly limited thereto. The cleaning solution may be, for example, at least one of isopropyl alcohol, acetone, and hydrochloric acid but is not limited thereto.

Then, as step (B) of the present invention, the step of forming the electrode layer 40 on the second conductive semiconductor layer 30 of the LED wafer 51 is performed. The electrode layer 40 may be formed through a typical method of forming an electrode on a semiconductor layer and may be formed by, for example, deposition through sputtering. The material of the electrode layer 40 may be, for example, ITO as described above, and the electrode layer 40 may be formed to have a thickness of about 150 nm. The electrode layer 40 may be further subjected to a rapid thermal annealing process after a deposition process. As an example, the electrode layer 40 may be processed at a temperature of 600° C. for 10 minutes. However, since the rapid thermal annealing process may be appropriately adjusted in consideration of the thickness and material of the electrode layer, the present invention is not particularly limited thereto.

Next, as step (C) of the present invention, the step of forming the plurality of micro-nanofin LED structures 52 by etching the LED wafer 51 in the thickness direction so that each element has a plane having a length and width of nano or micro size, and in which a thickness perpendicular to the plane is smaller than the length is performed.

Particularly, step (C) may be performed by including the steps of (C-1) forming a mask pattern layer 61 on the upper surface of the electrode layer 40 so that each element has the plane having a predetermined shape having a length and width of nano or micro size ((c) in FIG. 8), (C-2) forming the plurality of micro-nanofin LED structures 52 by etching a partial thickness of the first conductive semiconductor layer 10 in the thickness direction along the pattern of the mask pattern layer 61 ((d) in FIG. 8), (C-3) forming an insulating film 62 to cover the exposed side surface of each micro-nanofin LED structure 52 ((e) in FIG. 8), (C-4) removing a portion of the insulting film 62 formed on the first conductive layer so that the upper surface (part A in (f) in FIG. 8) of the first conductive semiconductor layer 10 between the adjacent micro-nanofin LED structures 52 is exposed, but the insulating film covering the side surface of the micro-nanofin LED structures 52 is not removed ((f) in FIG. 8), (C-5) forming the plurality of micro-nanofin LED structures in which a portion (part B in (g) in FIG. 8) of the side surface of the first conductive semiconductor layer 10 is exposed by further etching the exposed upper portion (part A in (f) in FIG. 8) of the first conductive semiconductor layer in the thickness direction ((g) in FIG. 8), (C-6) etching the first conductive semiconductor layer 10 from both sides in the width direction to the central side of the first conductive semiconductor layer 10 exposed from each micro-nanofin LED structure ((i) in FIG. 8), and (C-7) removing the mask pattern layer 61 disposed on the electrode layer 40 and the insulating film 62 covering the side surface ((j) in FIG. 8).

First, as step (C-1), the step of forming the mask pattern layer 61 on the upper surface of the electrode layer 40 so that each element has a plane having a predetermined shape having a length and width of nano or micro size ((c) in FIG. 8) may be performed.

The mask pattern layer 61 is a layer patterned so as to have a desired planar shape of the LED element to be implemented, and may be formed of a known method and material used for etching an LED wafer. The mask pattern layer 61 may be, for example, a SiO₂ hard mask pattern layer. Briefly describing the method of forming the SiO₂ hard mask pattern layer, the SiO₂ hard mask pattern layer may be formed by the steps of forming an unpatterned SiO₂ hard mask layer on the electrode layer 40, forming a metal layer on the SiO₂ hard mask layer, etching the metal layer and the SiO₂ hard mask layer in the thickness direction along the pattern, and removing the metal layer.

The mask layer is a layer from which the mask pattern layer 61 is derived. For example, SiO₂ may be formed through deposition. The mask layer may have a thickness of 0.5 to 3 μm, for example, 1.2 μm. In addition, the metal layer may be, for example, an aluminum layer, and the aluminum layer may be formed through deposition. The predetermined pattern formed on the formed metal layer is for realizing the pattern of the mask pattern layer, and may be a pattern formed by a conventional method. For example, the pattern may be formed through photolithography using a photosensitive material or may be a pattern formed through a known nanoimprinting method, laser interference lithography, electron beam lithography, or the like. Thereafter, the metal layer and the SiO₂ hard mask layer are etched along the formed pattern. For example, the metal layer may be etched using a drying etching such as an inductively coupled plasma (ICP), or the SiO₂ hard mask layer or the imprinted polymer layer may be etched using a dry etching method such as a reactive ion etching (RIE).

Next, the step of removing the metal layer or other photosensitive material layers remained on the upper portion of the etched SiO₂ hard mask layer, or the remaining polymer layer according to the imprint method may be performed. The removal may be performed through a conventional wet etching or dry etching method depending on the material, and detailed description thereof will be omitted in the present invention.

In FIG. 8, (c) is a plane view in which the SiO₂ hard mask pattern layer 61 is patterned on the electrode layer 40, and then, as (C-2) step, the step of forming the plurality of micro-nanofin LED structures 52 by etching a partial thickness of the first conductive semiconductor layer 10 in the thickness direction of the LED wafer 51 along the pattern may be performed as in (d) in FIG. 8. The etching may be performed through a conventional dry etching method such as ICP.

Thereafter, as step (C-3), as illustrated in (e) in FIG. 8, the step of forming the insulating film 62 to cover the exposed side surface of each micro-nanofin LED structure 52 may be performed. The insulating film 62 coated on the side surface may be formed through a deposition, and the material thereof may be, for example, SiO₂, but is not limited thereto. The insulating film 62 functions as a side mask layer, and specifically, as illustrated in (i) in FIG. 8, functions to prevent the portion to be the first semiconductor layer 10 of the micro-nanofin LED element 100 from being etched and prevent damage due to the etching in the process of etching a side portion (part B in (g) in FIG. 8) of the first conductive semiconductor layer 10 in the lateral direction to separate the micro-nano-fin LED structure 52. The insulating film 62 may have the thickness of 100 to 600 nm, but is not limited thereto.

Then, as step (C-4), as illustrated in (f) in FIG. 8, the step of removing a portion of the insulting film 62 formed on the first conductive layer so that the upper surface (A in (f) in FIG. 8) of the first conductive semiconductor layer 10 between the adjacent micro-nanofin LED structures 52 is exposed, but the insulating film covering the side surface of the micro-nanofin LED structures 52 is not removed may be performed. The removal of the insulating film 62 may be performed through an appropriate etching method in consideration of the material, and as an example, the insulating film 62 of SiO₂ may be removed through a dry etching such as RIE.

Then, as step (C-5), the step of forming the plurality of micro-nanofin LED structures in which a portion of the side surface of the first conductive semiconductor layer 10 is exposed by further etching the exposed upper portion (part A in (f) in FIG. 8) of the first conductive semiconductor layer in the thickness direction may be performed as in (g) in FIG. 8. As described above, the exposed side portion (B) of the first conductive semiconductor layer 10 is a portion on which a side etching is going to be performed in the horizontal direction to the substrate in the step to be described later. The process of further etching the first conductive semiconductor layer 10 in the thickness may be performed by a dry etching such as ICP, for example.

Then, as step (C-6), the step of side etching the portion of the first conductive semiconductor layer (B in (g) in FIG. 8) having the exposed side surface in the horizontal direction to the substrate may be performed. The side etching may be performed through a wet etching. For example, the wet etching may be performed at a temperature of 60 to 100° C. using a tetramethylammonium hydroxide (TMAH) solution.

After performing the wet etching in the lateral direction, as step (C-7), the step of removing the mask pattern layer 61 disposed on the electrode layer 40 and the insulating film 62 covering the side surface may be performed as in (j) in FIG. 8. Both materials of the mask pattern layer 61 and the insulating film 62 disposed on the upper portion may be SiO₂, and may be removed through a wet etching. For example, the wet etching may be performed using a buffer oxide etchant (BOE).

According to an embodiment of the present invention, as step (E) between steps (C) and (D) described above, the step of forming a protective film 50 on the side surfaces of the plurality of micro-nano-fin LED structures may be further performed. The protective film 50 may be formed by, for example, deposition, as illustrated in (k) in FIG. 8, and may have the thickness of 10 to 100 nm, for example, 40 nm, and the material of the protective film 50 may be, for example, alumina. In using alumina, an atomic layer deposition (ALD) method may be used as an example of the deposition. In addition, in order to form the deposited protective film 50 only on the side surfaces of the plurality of micro-nanofin LED structures, the protective film 50 positioned on the remaining portions except for the side surfaces may be removed by etching, for example, a dry etching through ICP. On the other hand, it should be noted that although (l) in FIG. 8 illustrates that the protective film 50 surrounds the entire side surface, the protective film 50 may not be formed on all or part of the remaining portions except for the photoactive layer on the side surface.

Then, as step (D) according to the present invention, the step of separating the plurality of micro-nanofin LED structures 52 from the LED wafer is performed as in (m) in FIG. 8. The separation may be a cutting using a cutting mechanism or a detaching using an adhesive film, but the present invention is not particularly limited thereto.

In addition, a method for manufacturing the micro-nanofin LED element 109 in which the polarization inducing layer 40′ is formed on the second conductive semiconductor layer 30 will be described with reference to FIG. 12.

The method for manufacturing the micro-nanofin LED element 109 in which the polarization inducing layer 40′ is formed differs from the method for manufacturing the micro-nano-fin LED element 100 in which the electrode layer 40 is formed only in step (B) in which the polarization inducing layer 40′ is formed instead of the electrode layer 40, and all other processes may be performed in the same manner.

Step (B) will be described in detail with reference to FIG. 12, as illustrated in (b), (c1), and (c2) in FIG. 12, the step of forming the polarization inducing layer 40′ on the second conductive semiconductor layer 30 is performed. The polarization inducing layer 40′ may be specifically patterned so that regions having different electrical polarities are adjacent to each other on the second conductive semiconductor layer 30 of the LED wafer 51. More specifically, step (2) may be performed by including the steps of (B-1) forming the first polarization inducing layer 41 on the second conductive semiconductor layer 30 ((b) in FIG. 12), (B-2) etching the first polarization inducing layer 41 in the thickness direction along a predetermined pattern (not illustrated), and (B-3) forming the second polarization-inducing layer 42 on the etched intaglio portion ((c1) and (c2) in FIG. 12). Step (2) which is different from the manufacturing method illustrated in FIG. 8 will be described below, and the rest of the description of FIG. 12 is substituted with the description of FIG. 8.

Step (2) is the step of forming the polarization inducing layer 40′ on the second conductive semiconductor layer 30, and more specifically, the polarization inducing layer 40′ may be manufactured through the following subdivided steps.

First, as step (B-1), the step of forming the first polarization inducing layer 41 on the second conductive semiconductor layer 30 ((b) in FIG. 12) is performed. The first polarization inducing layer 41 may be a conventional electrode layer formed on a semiconductor layer, and may be, for example, Cr, Ti, Ni, Au, ITO, etc., preferably ITO in terms of transparency. The first polarization inducing layer 41 may be formed through a conventional method of forming an electrode, and may be formed by, for example, deposition through sputtering. As an example, in the case that ITO is used, it may be deposited to a thickness of about 150 nm, and may be further subjected to a rapid thermal annealing process after the deposition process. For example, it may be treated at 600° C. for 10 minutes, but in consideration of the thickness, material, etc. of the first polarization inducing layer 41, the process can be appropriately adjusted, and the present invention is not particularly limited thereto.

Then, as step (B-2), the step of etching the first polarization inducing layer 41 in the thickness direction according to a predetermined pattern is performed. This step is a step of preparing a region in which the second polarization inducing layer 42 to be described later is to be formed, and the pattern may be determined in consideration of the area ratio and arrangement of the first polarization inducing layer 41 and second polarization inducing layer 42 in the element. For example, the pattern may be formed such that the first polarization inducing layer 41 and the second polarization inducing layer 42 are alternately arranged side by side, as can be seen in (d) in FIG. 12. Since the pattern can be formed by appropriately applying a conventional photolithography method or a nanoimprinting method, a detailed description thereof will be omitted in the present invention.

The etching may be performed by employing an appropriate known etching method in consideration of the material of the first polarization inducing layer 41. For example, in the case that the first polarization inducing layer 41 is ITO, it may be etched through a wet etching. In this case, the etched thickness may be etched up to the upper surface of the second conductive semiconductor layer 30, that is, all the ITO may be etched in the thickness direction, but is not limited thereto. Specifically, only a portion of the ITO is etched in the thickness direction, and the second polarization inducing layer 42 may be formed on the etched intaglio portion. In this case it should be noted that the upper layer of one end of the element may be formed in a two-layer structure in which the first polarization inducing layer 41, which is ITO, and the second polarization inducing layer 42 are stacked.

Next, as step (B-3), the step of (B-3) forming the second polarization inducing layer 42 on the etched intaglio portion ((c1) and (c2) in FIG. 12) may be performed. A material that has a different electrical polarity from that of the selected first polarization inducing layer 41 and is used in a typical LED may be used for the second polarization inducing layer, without limitation. For example, the material may be a metal or a semiconductor, specifically nickel or chromium. As the method for forming the second polarization inducing layer, a known method may be appropriately employed according to the material such as vapor deposition, so the present invention is not particularly limited thereto.

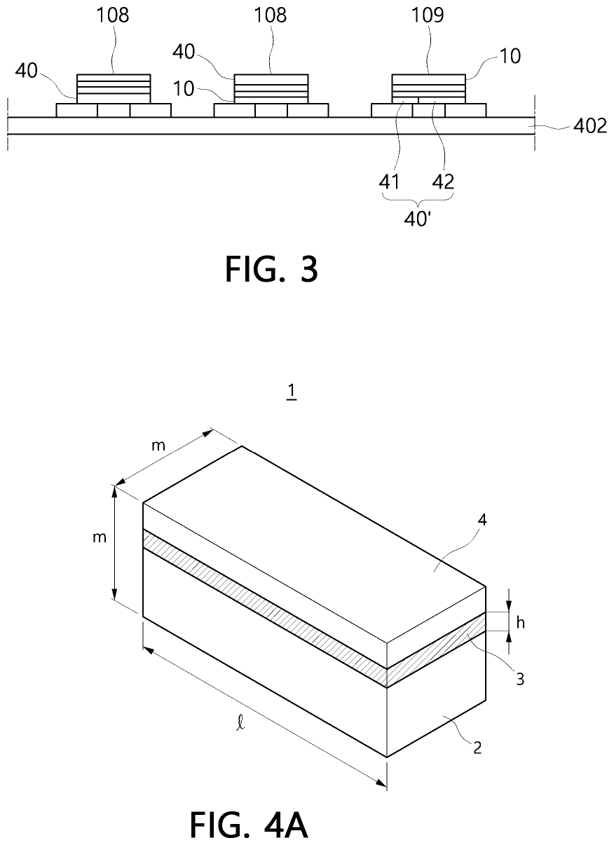

In the above-described micro-nanofin LED element 101, 102, 103, as illustrated in FIGS. 1 and 2, both ends in the longitudinal direction of the micro-nanofin LED element are in contact with two adjacent lower electrodes 211/212, 213/214, 215/216 of the lower electrode line 200, but one surface in the thickness direction, that is, the first conductive semiconductor layer 10 or the second conductive semiconductor layer 30 may be disposed to contact the lower electrodes 211, 212, 213, 214, 215, 216. In addition, in the case of further including the electrode layer 40 or the polarization inducing layer 40′, in the micro-nanofin LED element 108 having the electrode layer 40 as illustrated in FIG. 3, the electrode layer 40 is disposed to contact the upper surface of the lower electrode line formed on a base substrate 402, or one surface of the first conductive semiconductor layer 10 opposite to the electrode layer 40 is disposed in contact with the upper surface of the lower electrode line, and the electrode layer 40 may be disposed to contact an upper electrode line (not illustrated).

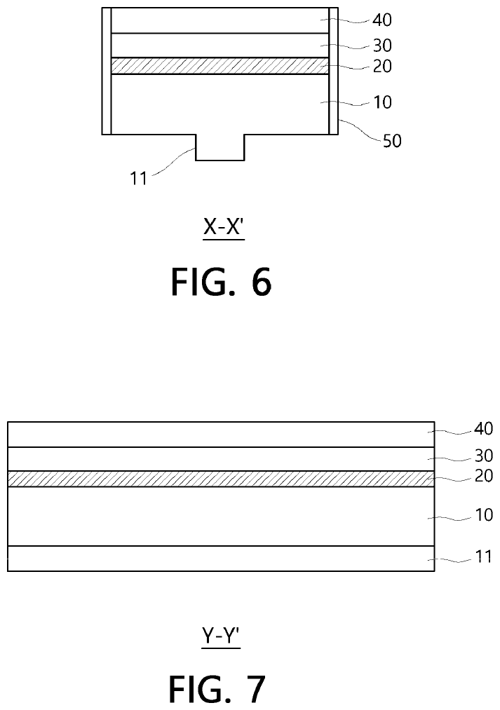

Meanwhile, in the case of the micro-nanofin LED element 109 further including the polarization inducing layer 40′, the polarization inducing layer 40′ may be disposed on the upper surface of the lower electrode line. However, it is noted that in the case of including the micro-nanofin LED element 109 further including a plurality of polarization inducing layers 40′, the polarization inducing layers 40′ of all micro-nanofin LED elements 109 are not disposed to be in contact with the upper surface of the lower electrode line, and the polarization inducing layer 40′ in the micro-nanofin LED element 109 may be disposed in contact with the lower electrode line with high probability due to the polarization inducing layer 40′, compared to the micro-nanofin LED element 108 having the electrode layer 40. On the other hand, the micro-nanofin LED element 108 having the electrode layer 40 and the micro-nanofin LED element 109 having the polarization inducing layer 40′ may include the protrusion (11 in FIG. 6, 11 in FIG. 11) on the lower surface of the first conductive semiconductor layer 10, as described above. The possibility of one side of the second conductive semiconductor layer 30 corresponding to the opposite surface to the surface on which the protrusion 11 is formed, that is, the electrode layer 40 or the polarization inducing layer 40′ being aligned so as to be in contact with the lower electrode line 200 may be increased due to the protrusion 11. Though this, alignment based on the thickness direction of the plurality of micro-nanofin LED elements in the micro-nanofin LED electrode assembly 1000 may be improved.

On the other hand, according to an embodiment of the present invention, as illustrated in FIG. 2, an electrical contacting metal layer 501 connecting the side surface of the conductive semiconductor layer (e.g., the first conductive semiconductor layer 10 in FIG. 2) of the micro-nanofin LED element 101, 102, 103 contacting the lower electrode line 200 and the lower electrode line 200 may be further included in order to reduce the contact resistance between the lower electrode line 200 and the micro-nanofin LED element 101, 102, 103. The electrical contacting metal layer 501 may be a conductive metal layer such as silver, aluminum, or gold, and for example, may be formed to have a thickness of about 10 nm.

In addition, an insulating layer 601 may be further included in a space between the micro-nanofin LED element 101, 102, 103 self-aligned on the lower electrode line 200 and the upper electrode line 300 in electrical contact with the micro-nanofin LED element 101, 102, 103. The insulating layer 601 prevents electrical contact between the two electrode lines 200, 300 facing each other in the vertical direction, and performs a function of facilitating the implementation of the upper electrode line 300. An insulating material commonly used in electrical and electronic components may be used as the insulating layer 601 without limitation.

A unit area capable of independently driving the above-described micro-nanofin LED electrode assembly 1000 is, for example, 1 μm² to 100 cm², and more preferably 10 μm² to 100 mm², but is not limited thereto. In addition, the micro-nanofin LED electrode assembly may include 2 to 100,000 micro-nanofin LED elements per unit area of 100×100 m² of the micro-nanofin LED electrode assembly, but is not limited thereto.

On the other hand, the micro-nanofin LED electrode assembly 1000 according to an embodiment of the present invention described above may be manufactured by including the steps of (1) adding a solution including the plurality of micro-nanofin LED elements 1,101,102,103,108,109 on the lower electrode line 200 including a plurality of lower electrodes 211, 212, 213, 214, 215, 216 spaced apart in the horizontal direction at a predetermined interval, (2) applying an assembly voltage to the lower electrode line 200 so that the first conductive semiconductor layer 10 or second conductive semiconductor layer 4,30 (or the electrode layer 40, or polarization inducing layer 40′) of the micro-nanofin LED element 1,101,102,103,108,109 in the solution is self-aligned to contact with at least two adjacent lower electrodes 211/212, 213/214, 215/216, and (3) forming the upper electrode line 300 on the plurality of self-aligned micro-nanofin LED elements 1,101,102,103,108,109.

First, as step (1) according to the present invention, the step of adding the solution including the plurality of micro-nanofin LED elements 1,101,102,103,108,109 on the lower electrode line 200 including the plurality of lower electrodes 211,212,213,214,215,216 spaced apart in the horizontal direction at a predetermined interval is performed.

The solution including the plurality of micro-nanofin LED elements 1,101,102,103,108,109 may include the plurality of micro-nanofin LED elements 1,101,102,103,108,109 and a solvent. The solvent has a function of dispersing the micro-nanofin LED element 1,101,102,103,108,109 as well as a function of moving the micro-nanofin LED element 1,101,102,103,108,109 to facilitate self-alignment on the lower electrode 211,212,213,214,215,216. In addition, the solution may be in the form of ink or paste, and the solution may be added onto the lower electrode line 200 using, for example, inkjet. On the other hand, although step (1) has been described as the LED element is added in a solution state mixed with the solvent, it is noted that the case in which the LED element is first added on the lower electrode line, and then the solvent is added is consequently the same as when the solution is added, and thus, this case is also included in step (1).

The solvent may be at least one selected from the group consisting of acetone, water, alcohol, and toluene, and more preferably acetone. However, the type of the solvent is not limited to the above description, and any solvent that can evaporate well without physically and chemically affecting the micro-nanofin LED element may be used without limitation. Preferably, the micro-nanofin LED element may be added in an amount of 0.001 to 100 parts by weight based on 100 parts by weight of the solvent. If the amount is less than 0.001 parts by weight, the number of micro-nanofin LED elements connected to the lower electrode may be small, so it can be difficult for the micro-nanofin LED electrode assembly to function normally, and there may be a problem in that the solution must be added dropwise several times to overcome the problem. When the amount exceeds 100 parts by weight, there may be a problem that the alignment of individual micro-nanofin LED elements may be disturbed.

Next, as step (2) according to the present invention, the step of applying an assembly voltage to the lower electrode line 200 so that the first conductive semiconductor layer 10 or second conductive semiconductor layer 30 (or the electrode layer 40, or polarization inducing layer 40′) of the micro-nanofin LED element 1,101,102,103,108,109 in the solution is self-aligned to contact with at least two adjacent lower electrodes 211/212, 213/214, 215/216 is performed.

Step (2) is the step in which charges are induced in the micro-nanofin LED element 1,101,102,103,108,109 by induction of the electric field formed by the potential difference between the lower electrodes 211/212, 213/214, 215/216 to which the micro-nanofin LED element is adjacent, and the micro-nanofin LED element 1,101,102,103,108,109 is self-aligned by inducing to have different charges toward both ends in the longitudinal direction around the center of the micro-nanofin LED element 1,101,102,103,108,109. The power may be applied to form the potential difference between any one of the two adjacent lower electrodes and the other, or between a first group consisting of two or more adjacent lower electrodes and a second group consisting of two or more adjacent lower electrodes adjacent to the first group, among the plurality of lower electrodes 211, 212, 213, 214, 215, 216 of the lower electrode line 200. In this case, as for the strength, type, etc. of the applied assembly voltage, the contents of Korean Patent Application Nos. 10-2013-0080412, 10-2016-0092737, 10-2016-0073572, etc. by the inventor of the present invention may be incorporated herein as reference.

Next, as step (3) of the present invention, the step of forming the upper electrode line 300 on the plurality of self-aligned micro-nanofin LED elements 1,101,102,103,108,109 is formed. The upper electrode line 300 may be implemented by depositing an electrode material after patterning the electrode line using known photolithography, or by depositing the electrode material and then dry and/or wet etching the electrode material. In this case, since the electrode material is the same as the electrode material of the lower electrode line described above, the description thereof will be omitted below.

On the other hand, the step of forming the electrical contacting metal layer 501 connecting the side surface of the first conductive semiconductor layer 10 or second conductive semiconductor layer of each of the micro-nanofin LED elements 101, 102, 103 in contact with the lower electrode line 200 and the lower electrode line and the step of forming the insulting layer 601 on the lower electrode line 200 not to cover the upper surface of the self-aligned micro-nanofin LED element 101, 102, 103 may be further included between steps (2) and (3) described above.

The electrical contacting metal layer 501 may be manufactured by patterning a line on which the electrical contacting metal layer is to be deposited by applying a photolithography process using a photosensitive material and then depositing the energizing metal layer, or by patterning the deposited metal layer and then etching the patterned metal layer. This process may be performed by appropriately employing a known method, and the content of Korean Patent Application No. 10-2016-0181410 by the inventor of the present invention may be incorporated herein by reference.

After forming the electrical contacting metal layer 501, the step of forming the insulating layer 601 on the lower electrode line 200 not to cover the upper surface of the self-aligned micro-nanofin LED element 101, 102, 103 may be performed. The insulating layer 601 may be formed through deposition of a known insulating material, for example, an insulating material such as SiO₂ or SiNₓ may be deposited through a PECVD method, an insulating material such as AlN or GaN may be deposited through a MOCVD method, or an insulating material such as Al₂O, HfO₂, ZrO₂ may be deposited through an ALD method. On the other hand, the insulating layer 601 may be formed not to cover the upper surface of the self-aligned micro-nanofin LED element 101, 102, 103. For this purpose, the insulating layer is formed through deposition to a thickness that does not cover the upper surface or to cover the upper surface, and then, dry etching may be performed until the upper surface of the element is exposed.

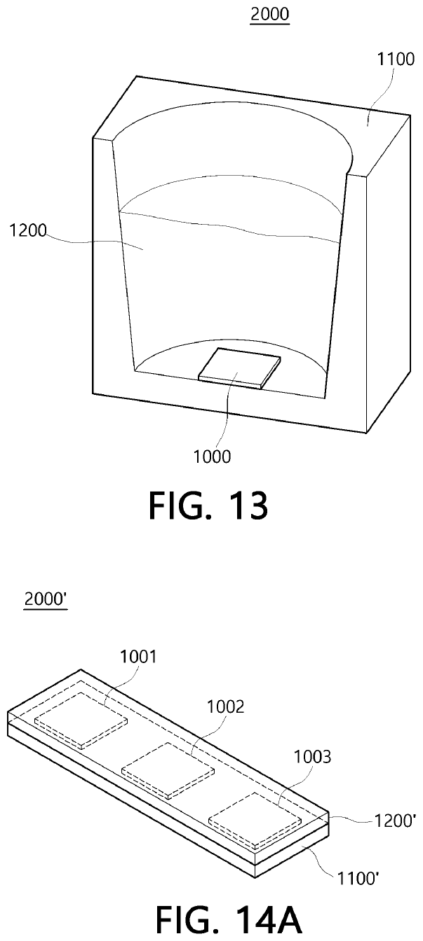

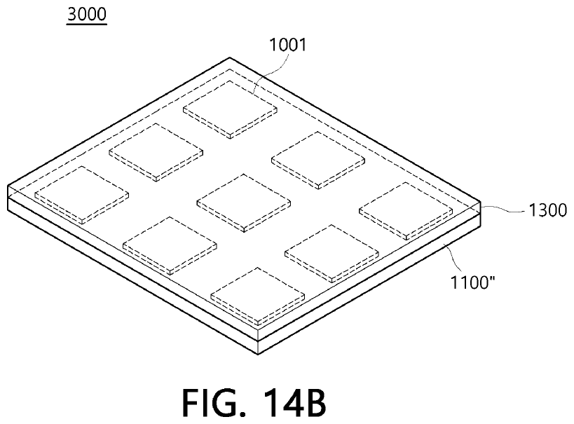

The above-described micro-nanofin LED electrode assembly 1000 may be applied to a known light source in which an LED element is employed. As an example, referring to FIGS. 13, 14A, and 14B, a light source 2000, 2000′, 3000 according to an embodiment of the present invention may be implemented to include the support body 1100, 1100′, 1100″ and the micro-nanofin LED electrode assembly 1000, 1001, 1002, 1003 provided on the support body 1100, 1100′, 1100″.

The support body 1100, 1100′, 1100″ is for supporting the micro-nanofin LED electrode assembly 1000, 1001, 1002, 1003, and any material that has a mechanical strength above a certain level to perform the support function may be used as the support body without limitation. As a non-limiting example, it may be at least one material selected from the group consisting of an organic resin, ceramic, metal, and an inorganic resin. In addition, the support body 1100, 1100′, 1100″ may be transparent or opaque.

In addition, the shape of the support body 1100, 1100′, 1100″ may be a cup shape as illustrated in FIG. 13 or a plate shape as illustrated in FIGS. 14A and 14B, but is not limited thereto, and the support body may have various shapes depending on the shape of the surface on which a light source is mounted. In addition, the area and/or volume of the support body 1100, 1100′, 1100″ may be also appropriately adjusted in consideration of a luminance characteristic to be implemented and the number/arrangement structure of the micro-nanofin LED electrode assembly 1000, 1001, 1002, 1003 provided accordingly, and the use of the light source, so the present invention is not particularly limited thereto. In addition, the thickness of the support body 1100, 1100′, 1100″ can be appropriately adopted to a thickness sufficient to support the micro-nanofin LED electrode assembly 1000, 1001, 1002, 1003 in consideration of the strength of the material.

In addition, it is noted that in addition to the function of supporting the micro-nanofin LED electrode assembly 1000, 1001, 1002, 1003, the support body 1100 illustrated in FIG. 13 itself can also serve as a housing of the light source.

In addition, the micro-nanofin LED electrode assembly 1000, 1001, 1002, 1003 may be provided in one or two or more in the light source 2000, 2000′, 3000. In this case, the micro-nanofin LED element 1, 101, 102, 103, 108, 109 provided in a single micro-nanofin LED electrode assembly 1000, 1001, 1002, 1003 may consist of an element that emits substantially any one color, and the light color may be, for example, any one of UV, blue, green, yellow, amber, and red. On the other hand, in the case that two or more micro-nanofin LED electrode assemblies 1001, 1002, 1003 are provided in the light source 2000′, 3000, and they are configured to be driven independently, the light source may be implemented to emit various types of light colors, and such a light source may be employed in a display such as LCD or OLED. In addition, in the case that two or more micro-nanofin LED electrode assemblies 1000, 1001, 1002, 1003 are included, the electrode assemblies may be arranged according to a rule such as a line arrangement in any one direction as illustrated in FIG. 14A or a plane arrangement as illustrated in FIG. 14B or may be arranged randomly otherwise.

In addition, the light source 2000, 2000′, 3000 may further include a color conversion material so that the light emitted from the micro-nanofin LED electrode assembly 1000, 1001, 1002, 1003 has a specific wavelength. The color conversion material is excited by the light emitted from the micro-nanofin LED element 1,101, 102, 103, 108, 109 to perform a function of emitting light having a specific wavelength. For example, in the case that the support body 1100 has a cup-shaped accommodating part therein as illustrated in FIG. 13, the color conversion material may be provided in an embedding layer 1200 in the accommodating part. Also, as illustrated in FIGS. 14A and 14B. in the case that the support body 1100′, 1100″ has a flat plate shape, the color conversion material may be provided in the form of a coating layer 1200′, 1300.

In addition, the micro-nanofin LED element 1,101,102,103,108,109 may be an element that emits any one light color of UV, blue, green, yellow, amber, and red. The color conversion material may be determined in consideration of the light color emitted by the selected element. For example, in the case of an element emitting UV light, the color conversion material may be any one or more of blue, cyan, yellow, green, amber, and red, through which a monochromatic light source of any one color or a white light source may be implemented. In the case of an element that emits UV as an example of implementing a white light source, the color conversion material may be a mixture material of any one of blue/yellow, red/cyan, blue/green/red, and blue/green/amber/red, and through this, a white light source can be implemented. In addition, in the case of an element emitting blue light, the color conversion material may be any one or more of yellow, cyan, green, amber, and red, and through this, a monochromatic light source or a white light source may be implemented. As an example of implementing the white light source, any two or more colors may be combined, and specifically, the white light source may be implemented through combination of a mixture material of any one of blue/yellow, red/cyan, blue/green/red, and blue/green/amber/red.

On the other hand, the color conversion material may be a known phosphor or quantum dot used for a lighting, a display, etc., and the present invention is not particularly limited with respect to the specific type thereof.

The above-described light source 2000, 2000′, 3000 may constitute an electric/electronic component or an electronic device by itself or in combination with other known configurations. For example, the known configuration may include an input unit for receiving signals necessary for operating the micro-nanofin LED electrode assembly 1000, 1001, 1002, 1003, a controller for controlling the signals, a heat dissipator such as a heat sink for transferring the heat generated during the operation of the micro-nanofin LED electrode assembly 1000, 1001, 1002, 1003 to the outside, a housing for packaging the light source with other components, and the like.

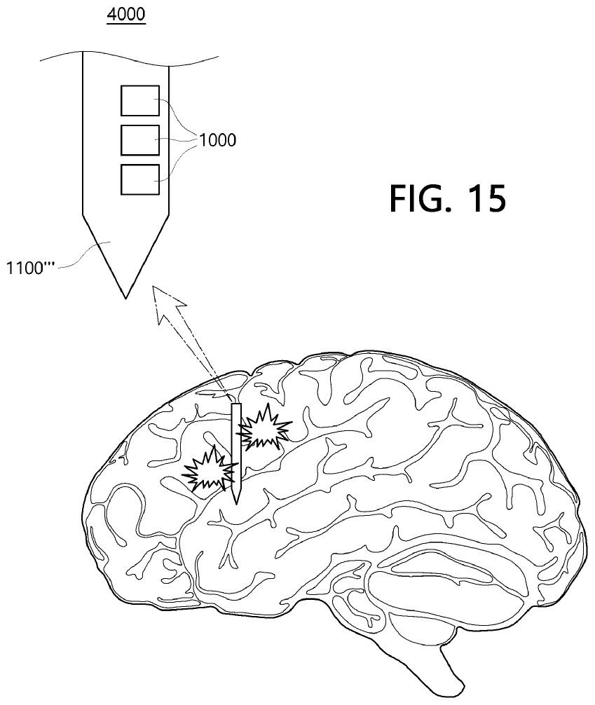

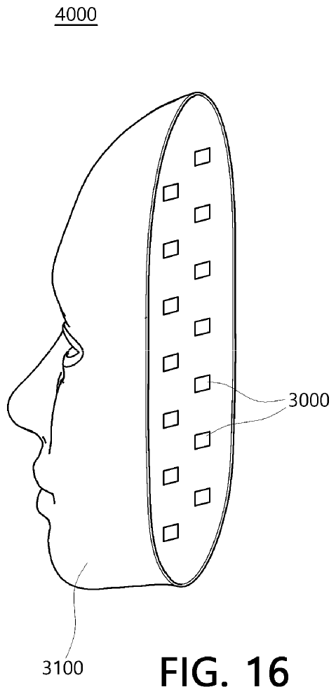

In addition, the light source 2000, 2000′, 3000 may be employed in various electrical and electronic devices that require a light emitting body, for example, various LED lights for home/vehicle use, displays, medical devices, beauty devices, and various optical devices. On the other hand, as illustrated in FIG. 15, the medical device may be, for example, an optogenetic LED light source 4000 that emits light of a predetermined wavelength to the brain to activate a neural network of a corresponding region. The optogenetic LED light source 4000 may include the plurality of micro-nanofin LED electrode assemblies 1000 on the support body 1100′″. In addition, the beauty device may be, for example, a skin beauty LED mask 5000 as illustrated in FIG. 16, and may be implemented to include the plurality of micro-nanofin LED electrode assemblies 1000 on the inner surface of a mask support body 3100 that comes into contact with the skin.

While the embodiments of the present invention have been described above, the present invention is not limited to the embodiment presented herein. One skilled in the art may easily suggest other embodiments due to addition, modification, deletion, adding, and the like of components within the scope and spirit of the present invention, and the addition, modification, deletion, adding, and the like of the components fall within the scope and spirit of the present invention.

1. A method for manufacturing a micro-nanofin LED electrode assembly, comprising the steps of:
(1) adding a solution including a plurality of micro-nanofin LED elements on a lower electrode line including a plurality of lower electrodes spaced apart in a horizontal direction at a predetermined interval, wherein the micro-nanofin LED element is a rod-type element including a plane having a length and width of nano or micro size and a thickness perpendicular to the plane smaller than the length, and in which a first conductive semiconductor layer, a photoactive layer, a second conductive semiconductor layer, and an electrode layer or a polarization inducing layer are sequentially stacked in a thickness direction;
(2) applying an assembly voltage to the lower electrode line so that the first conductive semiconductor layer, or electrode layer or polarization inducing layer of each of the plurality of micro-nanofin LED elements in the solution is in contact with at least two of the lower electrodes, thereby self-aligning the plurality of micro-nanofin LED elements; and
(3) forming an upper electrode line on the plurality of self-aligned micro-nanofin LED elements.

2. The method of claim 1, wherein the predetermined interval is smaller than the length of the micro-nanofin LED element.

3. The method of claim 1, further comprising, between the steps (2) and (3), the steps of:
(4) forming an electrical contacting metal layer connecting between a side surface of the first conductive semiconductor layer, electrode layer, or polarization inducing layer of each of the micro-nanofin LED elements in contact with at least two of the lower electrodes and the contacted lower electrodes; and
(5) forming an insulating layer on the lower electrode not to cover upper surfaces of the plurality of self-aligned micro-nanofin LED elements.

4. The method of claim 1, wherein the length of the micro-nanofin LED element is 1000 to 10000 nm, and the thickness of the micro-nanofin LED element is 100 to 3000 nm.

5. The method of claim 1, wherein a ratio of the length to the thickness of the micro-nanofin LED element is 3:1 or more.

6. The method of claim 1, wherein the micro-nanofin LED element further includes a protective film formed on a side surface of the micro-nanofin LED element to cover an exposed surface of the photoactive layer.

7. The method of claim 1, wherein the polarization inducing layer includes a first polarization inducing layer and a second polarization inducing layer disposed adjacently along a longitudinal direction of the micro-nanofin LED element, and the first polarization inducing layer and the second polarization inducing layer have different electrical polarities.

8. The method of claim 7, wherein the first polarization inducing layer is ITO, and the second polarization inducing layer is a metal or a semiconductor.

9. A micro-nanofin LED electrode assembly, comprising:
a lower electrode line including a plurality of lower electrodes spaced apart in a horizontal direction at a predetermined interval;
a plurality of micro-nanofin LED elements which is a rod-type element including a plane having a length and width of nano or micro size and a thickness perpendicular to the plane smaller than the length, and in which a first conductive semiconductor layer, a photoactive layer, a second conductive semiconductor layer, and an electrode layer or a polarization inducing layer are sequentially stacked in a thickness direction, and in which the first conductive semiconductor layer, or the electrode layer or the polarization inducing layer is disposed to be in contact with at least two of the lower electrodes; and
an upper electrode line disposed on the plurality of micro-nanofin LED elements.

10. The micro-nanofin LED electrode assembly of claim 9, wherein one of the first conductive semiconductor layer and the second conductive semiconductor layer includes a p-type GaN semiconductor layer, and the other includes an n-type GaN semiconductor layer,
a thickness of the p-type GaN semiconductor layer is 10 to 350 nm, a thickness of the n-type GaN semiconductor layer is 100 to 3000 nm, and a thickness of the photoactive layer is 30 to 200 nm.

11. The micro-nanofin LED electrode assembly of claim 9, wherein a protrusion having a predetermined width and thickness is formed on a lower surface of the first conductive semiconductor layer of the micro-nanofin LED element in a longitudinal direction of the micro-nanofin LED element.

12. The micro-nanofin LED electrode assembly of claim 11, wherein the width of the protrusion is formed to have a length of 50% or less compared to the width of the micro-nanofin LED element.

13. The micro-nanofin LED electrode assembly of claim 9, wherein an emission area of the micro-nanofin LED element is more than twice an area of a longitudinal cross-section of the micro-nanofin LED element.

14. A light source comprising:
a support body; and
the micro-nanofin LED electrode assembly of claim 9 provided so that the lower electrode line is disposed on the support body.

15. The light source of claim 14, further comprising a color conversion material excited by light irradiated from the micro-nanofin LED electrode assembly.

16. The light source of claim 14, wherein 2 to 100,000 micro-nanofin LED elements are included per unit area of 100×100 μm² of the micro-nanofin LED electrode assembly.

17. The light source of claim 14, wherein the micro-nanofin LED element emits any one type of light color among UV, blue, green, yellow, amber, and red.

18. The light source of claim 14, wherein a plurality of the micro-nanofin LED electrode assemblies is provided so as to emit at least two light colors of blue, green, yellow, amber, and red, and each of the micro-nanofin LED electrode assemblies includes the micro-nanofin LED element that emits substantially the same light color.

19. The light source of claim 15, wherein in a case that the micro-nanofin LED electrode assembly includes the micro-nanofin LED element irradiating UV, the color conversion material includes any one or more of blue, cyan, yellow, green, amber, and red, so that the light source is realized to emit white color, or
in a case that the micro-nanofin LED electrode assembly includes the micro-nanofin LED element that emits blue light, the color conversion material includes any one or more of yellow, cyan, green, amber, and red, so that the light source emits white color.
